(19) United States
(12) Patent Application Publication
(10) Pub. No.: US 2012/0153990 A1
(43) Pub. Date: Jun. 21, 2012

(54) EMBEDDED BLOCK CONFIGURATION VIA SHIFTING

(75) Inventor: ANTHONY STANSFIELD, Bristol (GB)

(73) Assignee: PANASONIC CORPORATION, Osaka (JP)

(21) Appl. No.: 12/971,435

(22) Filed: Dec. 17, 2010

(51) Int. Cl. H03K 19/177; H05K 13/00

(52) U.S. Cl. 326/41; 29/592.1

(57) ABSTRACT

A functional logic block for embedding into a reconfigurable array, the functional logic block comprises at least one multi-bit register including a plurality of single-bit registers, the single-bit registers being divided into at least two groups. The functional logic block also comprises a shift chain for connecting each group of single-bit registers, each shift chain being arranged to connect its respective group of single-bit registers into a configuration and test chain.

The present invention relates to application specific functional blocks embedded in reconfigurable logic devices. More specifically, the invention relates to a mechanism for configuring embedded functional blocks within a reconfigurable device.

Many modern reconfigurable devices, such as Field Programmable Gate Arrays (FPGAs) and D-Fabrix (as disclosed in, for example, U.S. Pat. No. 6,353,841, U.S. Pat. No. 6,252,792 and US2002/0157066), contain embedded functional blocks which implement a more restricted set of functions than the general-purpose processing elements, but which are useful in particular application areas. For example, FPGA devices often comprise embedded memories, multipliers and/or processor cores and D-Fabrix devices often comprise Algorithm Processing Units (APUs).

These blocks typically have a plurality of configuration states which determine the exact function of the blocks, and/or some data registers that may change state when the reconfigurable device is running. It is therefore necessary that the blocks be programmable via the configuration system of the reconfigurable device, and that the programming tools for the device should be able to generate appropriate programming data.

Automatic Test Pattern Generation (ATPG) tools are commonly used to create manufacturing tests for the logic in integrated circuits. They work by assuming that the circuit consists of blocks of combinatorial logic with inputs and outputs connected to registers. The ATPG tool calculates values to load into the input registers and expected values that will appear in the output registers if the circuit is operating correctly. These input values are chosen so that faults in the circuit will result in a different value appearing at one or more outputs. A complete test will normally require multiple input values, each able to detect a subset of the possible faults in the circuit. In the case of FPGAs, these tests can be applied using the device's configuration interface, as the configuration interface in FPGAs provides access to all stored states in the device. In the case of Application Specific Integrated Circuits (ASICs), a dedicated test access circuit is provided to load the relevant registers.

In a typical Application Specific Integrated Circuit (ASIC) environment, the test circuit typically links all the registers (both input and output) into one or more chains. The input values are shifted into the registers via these chains, and then propagated through the circuit before being loaded into the output registers. The output values are then read out via the register chain (or chains) and ultimately compared with the expected values in order to identify the presence or absence of a fault.

The test chains in ASIC devices can be laid out in any number of ways. Because the chain is being used solely for testing, and not configuration, the chains layout will be dictated principally by the physical proximity of groups of registers, rather than by the logical constraints needed to configure a device (e.g. the need to keep data coherently organised). Thus, in ASIC devices, it is relatively easy to create chains which minimise the longest distance between two connections, thereby reducing the chances of suffering timing constraints.

It is desirable to be able to set the state of the embedded functional block as part of the general configuration process because it is necessary to configure both the general-purpose logic and the embedded blocks(s) in order to set up the application in the reconfigurable device. It is also desirable to share configuration interface logic (such as the interface to external memory, and some control logic) between configuration of general-purpose logic and of embedded blocks, since this saves area (and therefore cost).

In the D-Fabrix architecture, in order to both test and configure the logic, it is preferable to use a single controller on one side of the reconfigurable array for both the sending and receiving of configuration and test data to/from the embedded functional block. The problem with creating the test chains by simply connected all the registers in a logical (i.e. logically coherent) order is that, in many cases, once the registers are linked, the end of the chain must then be connected to the single controller, which can be located on the other side of the embedded functional block. This long connection can in some situations impose serious timing constraints on the operation of the embedded functional blocks. These constraints are amplified when several embedded functional blocks are connected together in long columns.

Accordingly, there exists a need for an improved configuration chain for embedded functional blocks which will allow the input and output of the configuration chain to be adjacently located, and which will also allow multiple embedded functional blocks to be connected together without having negative effects on their performance.

In order to solve the problems associated with the prior art, the present invention provides a functional logic block for embedding into a reconfigurable array, the functional logic block comprises:

at least one multi-bit register including a plurality of single-bit registers, the single-bit registers being divided into at least two groups; and

a shift chain for connecting each group of single-bit registers, each shift chain being arranged to connect its respective group of single-bit registers into a configuration and test chain.

Preferably, a first group of registers represents the least significant bits of the multi-bit register and a second group of registers represents the most significant bits in the multi-bit register.

Preferably, the functional logic block comprises a plurality of single-bit input registers and a plurality of single-bit output registers.

Preferably, the single-bit input registers are divided into a first group and a second group and the plurality of single-bit output registers are divided into a third group and a fourth group.

Preferably, the first group is connected via a first shift chain extending in a first direction and the second group is connected via a second shift chain extending in a second direction, the second direction being opposite to the first direction, and wherein the third group is connected via a third shift chain extending in the first direction and the fourth group is connected via a fourth shift chain extending in the second direction.

The end of the first shift chain can be connected to the beginning of the second shift chain and the end of the third shift chain is connected to the beginning of the fourth shift chain.

Alternatively, the end of the first and third shift chains and the beginnings of the second and fourth shift chains can be connected to another functional logic block.

The present invention also provides a reconfigurable device which comprises:

an array of logic tiles; and

at least one functional logic block as described above.

Preferably, the configuration and test chains of at least two of the plurality of functional logic blocks are connected together to form a single configuration and test chain.

The present invention also provides a System on Chip comprising at least one reconfigurable device as described above, and wherein at least one test chain of the System on Chip is connected to the configuration and test chain of the at least one functional logic block of the at least one reconfigurable device.

Finally, the present invention provides a method of forming a configuration and test chain in a functional logic block having at least one multi-bit register including a plurality of single-bit registers, the method comprises the steps of:

grouping the plurality of single-bit registers into at least two groups; and

linking the registers of each group into a single shift chain.

Preferably, the method further comprises:

linking at least two shift chains together to form a configuration and test chain.

Preferably, the plurality of single-bit registers are grouped into a first group representing the most significant bits of the multi-bit register and a second group representing the least significant bits of the multi-bit register.

Preferably, the embedded functional block is used in a reconfigurable device which forms part of a System on Chip, the System on Chip having a test chain, and wherein the method further comprises the step of: connecting the configuration and test chain of the functional logic block to the test chain of the System on Chip.

As will be appreciated, the present invention provides several advantages. For example, the present invention provides a way to solve the above problems simultaneously, especially in the context of a reconfigurable core that is to be embedded in a larger (System on Chip) SoC device. In this context, where the embedded functional blocks are tailored to the target application space of the SoC, it is especially important to minimise the development time, so that multiple cores (with different embedded blocks) can be developed for use in multiple SoCs with different target applications. In particular it is intended to make it easy to support multiple types of embedded functional blocks within a family of reconfigurable devices and use a standard ATPG (Automatic Test Pattern Generation) tool to generate test patterns for the embedded functional blocks.

Moreover, the present invention provides a simple way to modify embedded functional blocks which were originally created to be used in ASIC devices, with a view to efficiently using them in reconfigurable devices.

Furthermore, the present invention provides an array which can use the same test circuit as the rest of the SoC. That is to say that it is possible to connect some of the test chains of the SoC to the configuration/test chains of the embedded functional blocks of the present invention. Accordingly, the embedded functional blocks of the present invention can be tested in exactly the same way as the other ASIC-style logic in the rest of the SoC.

Specific embodiments of the present invention will now be described in relation to the accompanying drawings, in which:

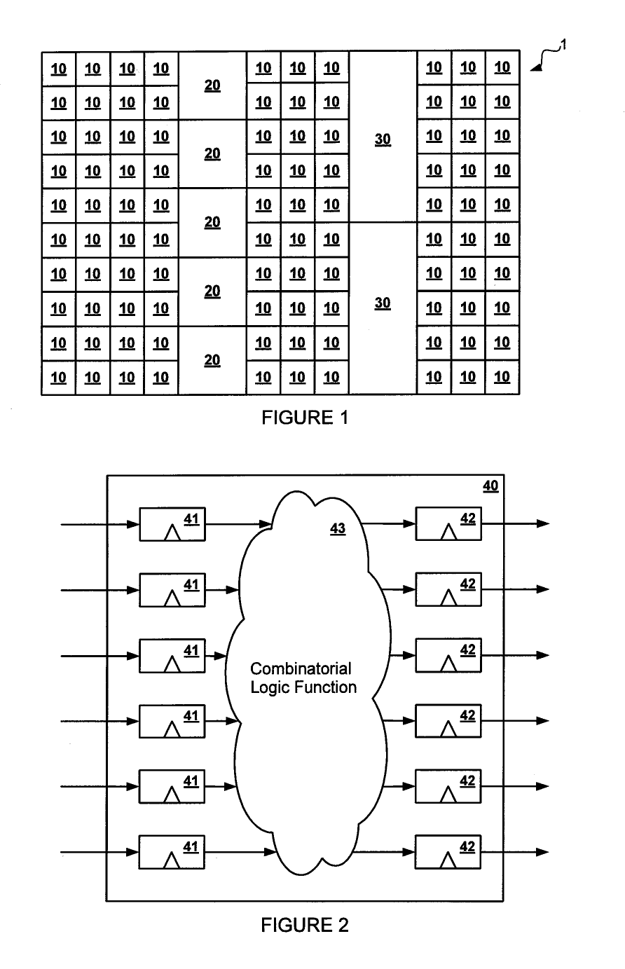

FIG. 1 shows a representation of a reconfigurable device comprising embedded functional units arranged in columns;

FIG. 2 shows a basic representation of a circuit for test generation;

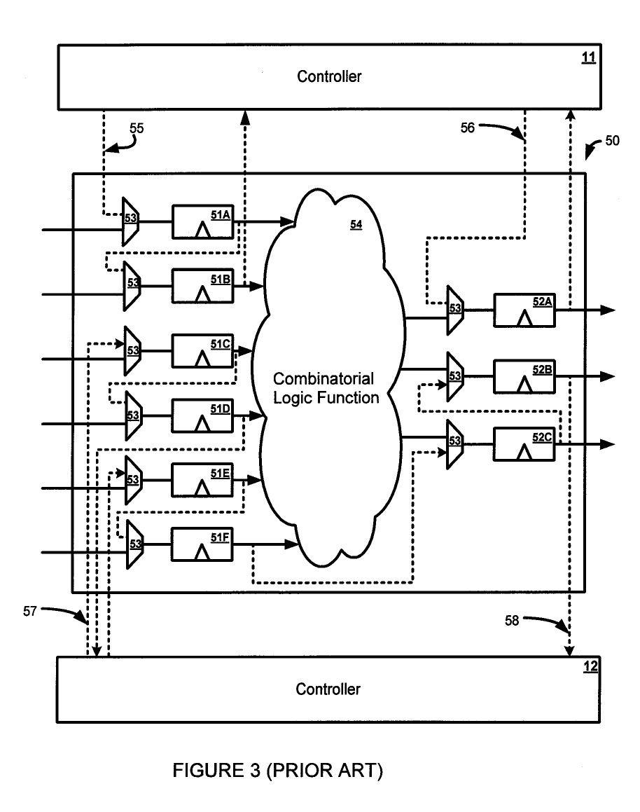

FIG. 3 shows a representation of a configuration chain of an embedded functional block in the ASIC environment;

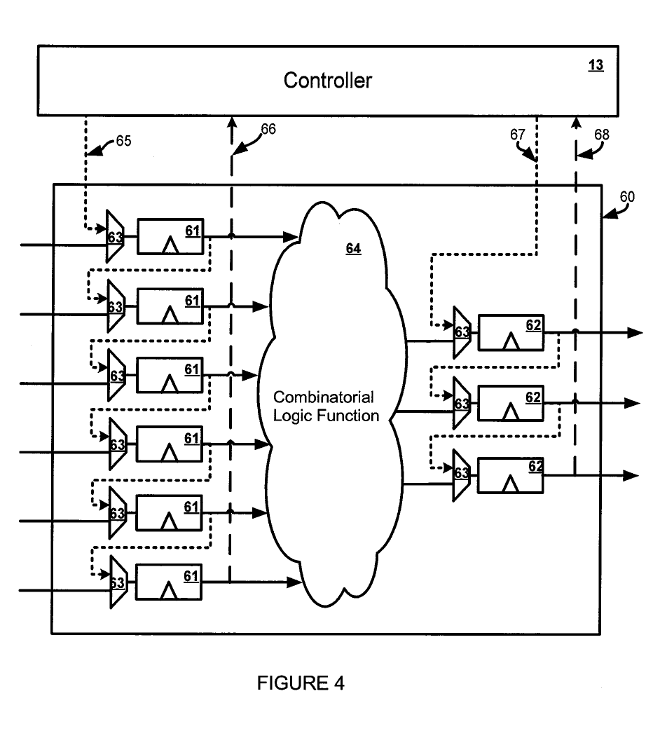

FIG. 4 shows a representation of a configuration chain of an embedded functional block in accordance with the prior art;

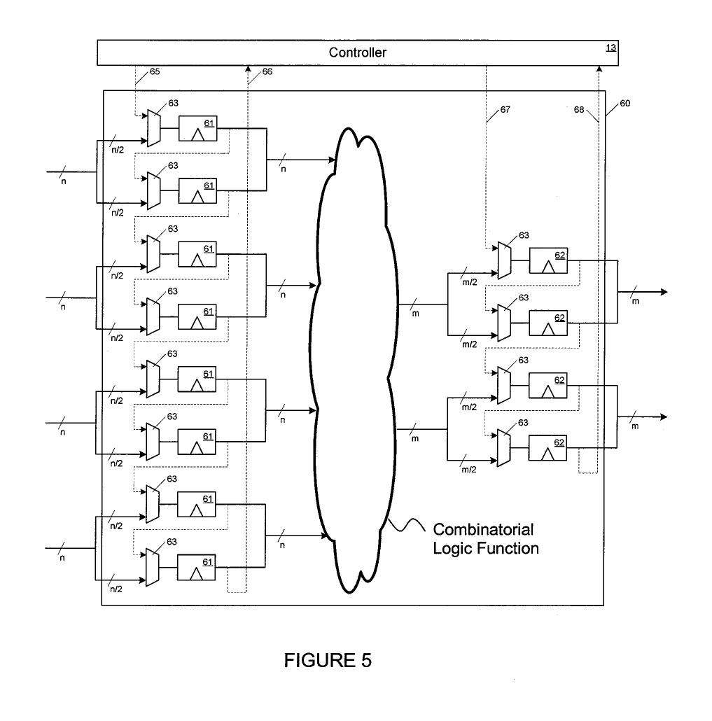

FIG. 5 shows a modified view of the embedded functional block of FIG. 4;

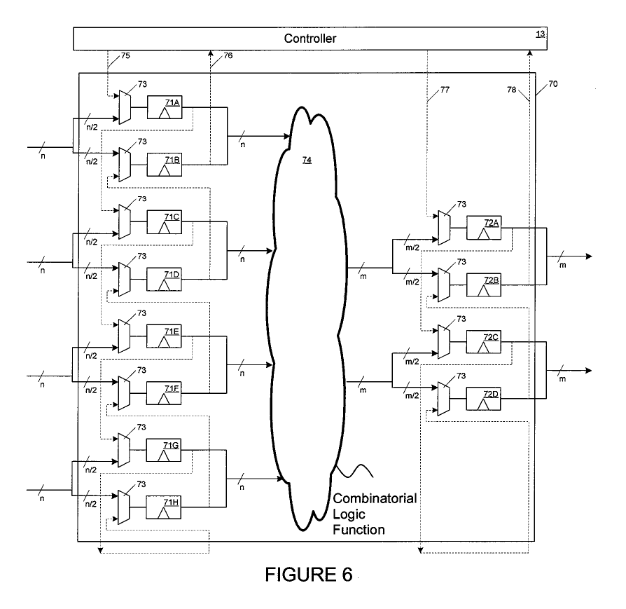

FIG. 6 shows a representation of an embedded functional block having registered inputs and outputs in accordance with the present invention;

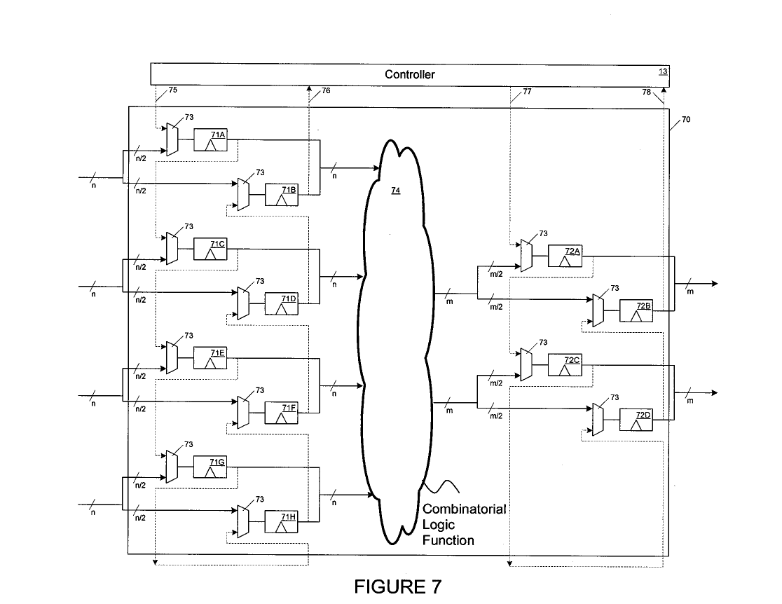

FIG. 7 shows a different representation of the configuration chain of an embedded functional block in accordance with the present invention;

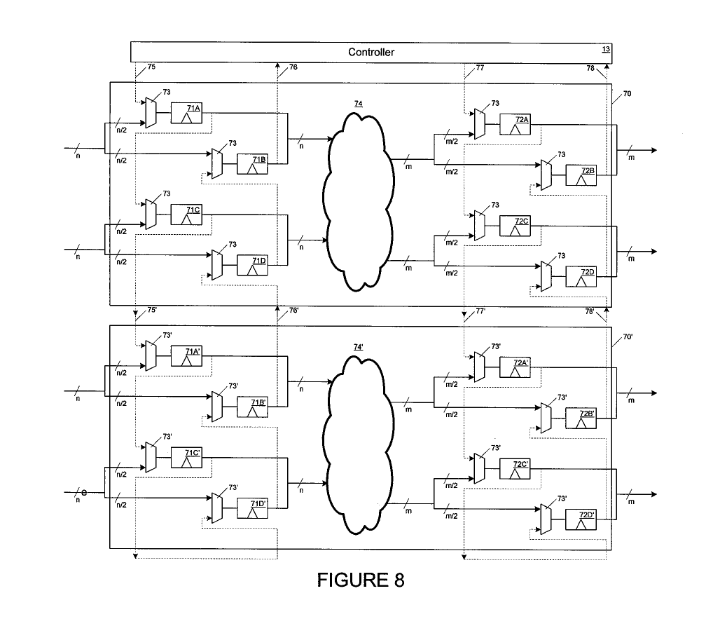

FIG. 8 shows a detailed representation of two embedded functional blocks in accordance with the present invention; and

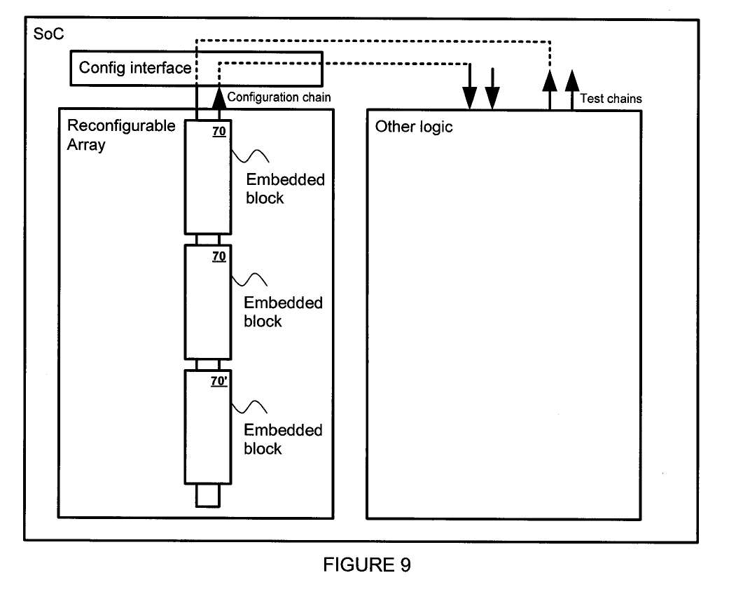

FIG. 9 shows how the present invention can be integrated into the ASIC style logic of a System on Chip (SoC).

FIG. 1 shows a typical reconfigurable device 1 having a plurality of different types of functional blocks 20, 30 embedded in an array of reconfigurable tiles 10. These embedded functional block 20, 30 are commonly organised in rows and columns. Each row or column typically contains multiple blocks, most commonly multiple instances of the same basic function. For instance, an array may contain column(s) of memories 20, and/or column(s) of multipliers 30. It is noted that these embedded blocks are invariably larger and more complex functional units than those that make up the basic reconfigurable array.

The situation shown in FIG. 1, where each embedded block in a column spans multiple rows of the basic processing elements of the array is typical. It is very common for the embedded blocks to have inputs that are organised as words (e.g. memory address and data buses, and the numeric inputs to multipliers), even if the reconfigurable logic is bit-based.

FIG. 2 represents a typical embedded functional block 40 having registered inputs and outputs, and some combinatorial logic function 43 there between. As will be appreciated, some embedded functional blocks will have unregistered inputs/outputs, and may also include bypassable registers. Also, some registers may act as both inputs and outputs in some embedded functional blocks. The inputs comprise registers 41 and the outputs comprise registers 42.

FIG. 3 shows an example of how the test chain of a typical ASIC device may be built. In order to load the registers for testing, a plurality of testing chains 55, 56, 57 and 58 are used, as shown in FIG. 3. FIG. 3 shows an embedded functional block 50 having registered inputs and outputs. In this example, the input registers 51A and 51B are connected to test chain 55.

The first two inputs of the embedded functional block 50 are connected to a first input of multiplexers 53, respectively. The second input of each multiplexer 53 in the chain is connected to the output of the register immediately before it in the test chain, whilst the output of each multiplexer 53 is connected to the register immediately after it in the test chain. The second input of the first multiplexer 53 in test chain 55 is connected to the controller 11 and the output of register 51B in the test chain 55 is connected directly to the controller 11.

The other test chains 56 57 and 58 are similarly configured. Test chain 56 comprises output register 52A, test chain 57 comprises input registers 51C and 51D, test chain 58 comprises input registers 51E and 51F as well as output registers 52B and 52C. How the registers are connected will depend on their physical location. As will be appreciated, FIG. 3 is a functional representation of the embedded functional block and does not necessarily show the actual physical layout of the registers.

In order to adapt the device of FIG. 3 for use in a D-Fabrix environment, where the beginning and ends of the test chains are to be located in the same area, and the registers must be laid out in logically coherent order, prior art solutions point to the use of a single chain 65, 66 for input registers and a single chain 67, 68 for output registers, as shown in FIG. 4.

The inputs comprise registers 61 and the outputs comprise registers 62. Similarly to the device of FIG. 3, in order to load the registers for configuration or testing, a plurality of configuration and testing chains 65, 66, 67, 68 are used.

FIG. 4 shows an embedded functional block 60 having registered inputs and outputs. In this example, the input registers 61 are connected to a configuration chain 65, 63, 66, which configuration chains are comprised of wired connections 65, 66 and multiplexers 63. The inputs of the embedded functional block 60 are connected to a first input of multiplexers 63, respectively. The second input of each multiplexer 63 is connected to the output of the register immediately before it in the configuration chain, whilst the output of each multiplexer 63 is connected to the register immediately after it in the configuration chain 65, 63, 66. The second input of the multiplexer 63 in the configuration chain 65, 63, 66 is connected to the controller 13, via a wired connection 65. The output of the last register 61 is also connected directly to the controller 13, via the wired return connection 66. The wired return connection 66 is a long wire which will reduce the maximum clock frequency of the embedded functional unit 60.

In the case of small arrays having only one or two interconnected embedded functional blocks, this problem may not significantly affect performance. When several of these blocks are interconnected however, the return connections will be connected together into a single long chain, which will impose significant timing constraints on the embedded functional block, which timing constraints will negatively impact the performance of the device.

The only known way of remedying this problem is by creating chains which are based on the physical disposition of the registers. Doing so however will preclude the device's ability to use the chains for propagating configuration data, as this data, dissimilarly to test data, must be distributed in a logically intelligible way.

Typically, most embedded functional blocks of this type have word-based inputs and outputs, as shown in FIG. 5, where the words input into the embedded functional block 70 are n bits wide, and the outputs are m bits wide. The present invention takes advantage of this by dividing each word-wide register in the block into 2 sections. These will typically be approximately equal in size (in terms of the number of bits), for instance the most-significant and least-significant halves of a numeric value. A separate configuration and test chain is then constructed for each of the two sections, as shown in FIG. 6.

FIG. 6 shows an embedded functional block 70 having registered inputs and outputs. In this example, a first group of input registers 71A, 71C, 71E and 71G are connected to a downward configuration and test chain 75, which configuration and test chain comprises wired connections 75 and multiplexers 73. A second group of registers 71B, 71D, 71F, 71H is connected to an upward configuration and test chain 76, consisting of wired connections 76 and multiplexers 73. Similarly, a first group of output registers 72A and 72C are connected in a downward configuration and test chain which comprises wired connections 77 and multiplexers 73. A second group of output registers 72B and 72D are connected in an upward configuration and test chain comprising wired connections 78 and multiplexers 73.

The first of these chains 75 (where the wired connection of this chain is shown in a dotted line in FIG. 6) is arranged to run from the controller 13 to the bottom of the embedded functional block 70, though a first group of registers, and the second of these chains 76 (where the wired connection of this chain is shown in a dashed line in FIG. 6) is arranged to run from the bottom of the embedded functional block 70 back towards the controller 13, through a second group of registers. One example of such an arrangement would be where the most-significant register bits could be situated on the downward chain 75 and the least significant register bits could be situated on the upwards chain 76. As will be appreciated many other logical divisions could be used in the grouping of the registers.

At the bottom of the column, the output of the downward chain is connected back to the input of the upward chain. Alternatively, these connections could be used to link a plurality of the “stacked” embedded functional blocks 70 together. Thus all bits associated with a particular word-wide register end up as part of the same long chain.

The same chain is used for both test access purposes and configuration access, i.e. it is connected to the configuration port of the reconfigurable array, so that the registers 71 can be initialised as part of the configuration of the array. This organisation ensures that the test chains start and finish on the same side of the array (i.e. at the top of the column). As mentioned above, this is a useful result, as it simplifies connection to the configuration control circuits. It also means that all register bits relating to a particular word-wide register are located in the same chain. This makes it easy to integrate the embedded block into the programming toolchain. It is expected that an embedded block may contain multiple word-wide registers. Each such register may be allocated its own chain, organised as described above.

FIG. 7 shows a clearer representation of the device of FIG. 6. As can be seen from FIG. 7, the longest wired connection between any two registers is significantly shorter that the wired connections 66 and 68 of FIG. 5. In this example, the input registers 71 are divided into two groups, a first group being part of the downward configuration and test chain 73 and a second group being part of the upward configuration and test chain 71. The output registers are also divided into two groups, a first group being part of the downward configuration and test chain 77 and a second group being part of the upward configuration and test chain 78. As will be appreciated, the downward and upward chains can be connected in any number of known ways. In this example, the downward chain is simply looped back to form the upward chain.

A column of embedded blocks may contain more that one block, as shown in FIG. 8, where the chains of a first embedded functional block 70 are connected to the chains of a second embedded functional block 70′, before being looped back at the bottom of this second block. In this example, the chains in each embedded functional block 70, 70′ are arranged in a similar manner to those shown in FIG. 6. The present invention is particularly advantageous in this situation, as the length of the long return wires 66 and 68 of FIG. 4 would be multiplied by however many embedded functional blocks would be interconnected in the column.

A column of embedded blocks may also contain more than one type of block. In this situation, it is preferable connect the chains between blocks so that registers with similar functions in the 2 types of blocks are part of the same chain (e.g. a chain contains input registers from both types of block, or output registers, but not a combination of both). Also, if there are multiple chains through the blocks, then they should be the same length. This means that a particular bit position in any chain through a column should always be located in the same embedded block in the column. Complying with this requirement may require adding a small number of extra registers into some blocks in order to balance chain lengths. Such additions are basically a tradeoff between hardware size and software complexity.

FIG. 9 shows how the present invention can be incorporated in a typical SoC in such a way as to use the same test chain used by the rest of the ASIC-style logic in the SoC. Thus, some of the test chains of the SoC can be connected to the configuration/test chains of an embedded functional block in accordance with the present invention. The embedded functional blocks of the present invention can therefore be tested in exactly the same way as the other ASIC-style logic in the rest of the SoC.

1. A functional logic block (70) for embedding into a reconfigurable array, the functional logic block comprising:
at least one multi-bit register including a plurality of single-bit registers (71A-71H, 72A-72D), the single-bit registers being divided into at least two groups; and
a shift chain for connecting each group of single-bit registers, each shift chain being arranged to connect its respective group of single-bit registers into a configuration and test chain.

2. The functional logic block (70) of claim 1, wherein a first group of registers represents the least significant bits of the multi-bit register and a second group of registers represents the most significant bits in the multi-bit register.

3. The functional logic block (70) of any of the preceding claims, wherein the functional logic block comprises a plurality of single-bit input registers (71A-71H) and a plurality of single-bit output registers (72A-72D).

4. The functional logic block (70) of claim 3, where the single-bit input registers (71A-71H) are divided into a first group and a second group and the plurality of single-bit output registers (72A-72D) are divided into a third group and a fourth group.

5. The functional logic block (70) of claim 4, wherein the first group is connected via a first shift chain extending in a first direction and the second group is connected via a second shift chain extending in a second direction, the second direction being opposite to the first direction, and wherein the third group is connected via a third shift chain extending in the first direction and the fourth group is connected via a fourth shift chain extending in the second direction.

6. The functional logic block (70) of claim 5, wherein the end of the first shift chain is connected to the beginning of the second shift chain and the end of the third shift chain is connected to the beginning of the fourth shift chain.

7. The functional logic block (70) of claim 5, wherein the end of the first and third shift chains and the beginnings of the second and fourth shift chains are connected to another functional logic block.

8. A reconfigurable device (1) comprising:
an array of logic tiles (10); and
at least one functional logic block (70) in accordance with any of the preceding claims.

9. The reconfigurable device (1) of claim 8, wherein the reconfigurable device comprises a plurality of functional logic blocks in accordance with any of claims 1 to 7, and wherein the configuration and test chains of at least two of the plurality of functional logic blocks are connected together to form a single configuration and test chain.

10. A System on Chip comprising at least one reconfigurable device (1) in accordance with any of claim 8 or 9, and wherein at least one test chain of the System on Chip is connected to the configuration and test chain of the at least one functional logic block (70) of the at least one reconfigurable device.

11. A method of forming a configuration and test chain in a functional logic block having at least one multi-bit register including a plurality of single-bit registers (71A-71H, 72A-72D), the method comprising the steps of:
grouping the plurality of single-bit registers into at least two groups; and
linking the registers of each group into a single shift chain.

12. The method of claim 11, further comprising:
linking at least two shift chains together to form a configuration and test chain.

13. The method of any of claim 11 or 12, wherein the plurality of single-bit registers are grouped into a first group representing the most significant bits of the multi-bit register and a second group representing the least significant bits of the multi-bit register.

14. The method of any of claims 12 to 13, wherein the embedded functional block is used in a reconfigurable device (1) which forms part of a System on Chip, the System on Chip having a test chain, and wherein the method further comprises the step of:
connecting the configuration and test chain of the functional logic block to the test chain of the System on Chip.
